(19) United States
(12) Patent Application Publication
(10) Pub. No.: US 2004/0263359 A1
(43) Pub. Date: Dec. 30, 2004

(54) Transducer assembly

(76) Inventors: Patrick A. Hampton, Deerfield Beach, FL (US); Jeffrey M. Buczek, Plantation, FL (US); Julio C. Castaneda, Coral Springs, FL (US)

Correspondence Address: Larry G. Brown, Motorola, Inc., Law Department, 8000 West Sunrise Boulevard, Fort Lauderdale, FL, 33322, US

(21) Appl. No.: 10/608,691

(22) Filed: Jun. 27, 2003

(51) Int. Cl. H03M 11/00; H03K 17/94

(52) U.S. Cl. 341/22

(57) ABSTRACT

A transducer assembly (100) and a method for producing same. The transducer assembly (100) includes a transducer (110), a flexible circuit element (112) in which the transducer (110) is coupled to the flexible circuit element (112) and a transducer seal (114). The transducer seal (114) seals the transducer (110) when the transducer seal (114) is positioned between a cover (125) and the flexible circuit element (112). The flexible circuit element (112) can be coupled to a display (120) and a circuit board (124). The display (120), the circuit board (124), the transducer (110), the flexible circuit element (112) and the transducer seal (114) can be housed within a telecommunications device (200). In addition, the circuit board (124) can include a zero insertion force connector (132) for receiving the flexible circuit element (112).

### CROSS REFERENCE TO RELATED APPLICATIONS

(Not Applicable)

### BACKGROUND

1. Technical Field

This invention relates in general to audio systems and more particularly, to telecommunications devices having multiple levels of audio output.

2. Description of the Related Art

Many mobile communications units support dual communication modes. In particular, a dual communication mode mobile unit can support both cellular telephone service and dispatch service. The audio levels between the two modes can vary. Specifically, the level of the audio output of the mobile unit when a user is engaged in a cellular call may be much lower than that of the audio output when the dispatch service is initiated. To accommodate the different levels of audio, mobile units that support both of these communication modes typically include two speakers, a relatively smaller speaker for the cellular communication and a relatively larger speaker for the dispatch service.

In view of this configuration, it is necessary to isolate the smaller speaker from the larger speaker. If the smaller speaker is not isolated from the larger one, the high level of audio output from the larger speaker may leak into the area housing the smaller speaker and may exit from the smaller speaker. This breach can be dangerous, particularly if a user has his or her ear pressed up against the portion of the mobile unit housing the smaller speaker.

### SUMMARY OF THE INVENTION

The present invention concerns a transducer assembly. The transducer assembly includes a transducer, a flexible circuit element in which the transducer is coupled to the flexible circuit element and a transducer seal. The transducer seal seals the transducer when the transducer seal is positioned between a cover and the flexible circuit element. In one arrangement, the flexible circuit element can be coupled to a display and a circuit board. Additionally, the display, the circuit board, the transducer, the flexible circuit element and the transducer seal can be housed within a telecommunications device. The circuit board may also include a zero insertion force connector for receiving the flexible circuit element.

In another aspect, the transducer assembly can further include an extension of a lightguide in which at least a portion of the flexible circuit element can be positioned on and secured to the extension of the lightguide. The extension of the lightguide can be positioned above a circuit board housed in a telecommunications device in which at least a portion of at least one circuit element can be mountable on the circuit board in an area that is below the extension of the lightguide.

In another embodiment, the cover can include a housing and a bezel. The housing can engage the bezel, and the lightguide can engage the housing. When the lightguide engages the housing and the housing engages the bezel, the transducer seal can be positioned against the housing and the bezel. Additionally, the transducer seal can include a front portion having a first rim and a back portion having a second rim. When the transducer seal is positioned against the housing and the bezel, the first rim of the front portion of the transducer seal can engage the bezel with a sealing interference fit. Further, when the transducer seal is positioned against the housing and the lightguide engages the housing, the second rim of the back portion of the transducer seal can engage the flexible circuit element with a sealing interference fit. In another arrangement, the transducer can include at least one spring contact for coupling the transducer to the flexible circuit element.

The transducer seal can include an aperture for receiving the transducer, a plate that covers a first end of the aperture and a first rim. Further, at least a portion of the first rim can extend above the plate. When the transducer is inserted into the aperture, a bottom surface of the first rim of the transducer seal can engage the transducer with a sealing interference fit, and an inner surface of the aperture of the transducer seal can engage the transducer with a sealing interference fit. In another embodiment, the transducer seal can be constructed of rubber or plastic, and the seal that is formed can prevent high audio leakage through the transducer assembly. In yet another arrangement, the extension of the lightguide can include at least one leg in which the leg can be positioned against a surface of the circuit board for supplementally supporting the lightguide.

The present invention also concerns a method for producing a transducer assembly. The method includes the steps of providing a transducer and a flexible circuit element, coupling the transducer to the flexible circuit element and positioning a transducer seal between a cover and the flexible circuit element to seal the transducer. The method can further include the steps of providing an extension of a lightguide and securing the flexible circuit element to the extension of the lightguide. In addition, the method can include the step of positioning the lightguide above a circuit board housed in a telecommunications device. At least a portion of at least one circuit element can be mountable on the circuit board in an area that is below the extension of the lightguide.

### BRIEF DESCRIPTION OF THE DRAWINGS

The features of the present invention, which are believed to be novel, are set forth with particularity in the appended claims. The invention, together with further objects and advantages thereof, may best be understood by reference to the following description, taken in conjunction with the accompanying drawings, in the several figures of which like reference numerals identify like elements, and in which:

FIG. 1 is an exploded frontal view of a transducer assembly in accordance with the inventive arrangements.

FIG. 2 is an exploded back view of a transducer assembly in accordance with the inventive arrangements.

FIG. 3 is a cross-sectional view of the transducer assembly of FIGS. 1 and 2 in accordance with the inventive arrangements.

### DETAILED DESCRIPTION OF THE PREFERRED EMBODIMENT

While the specification concludes with claims defining the features of the invention that are regarded as novel, it is believed that the invention will be better understood from a consideration of the following description in conjunction with the drawing figures, in which like reference numerals are carried forward.

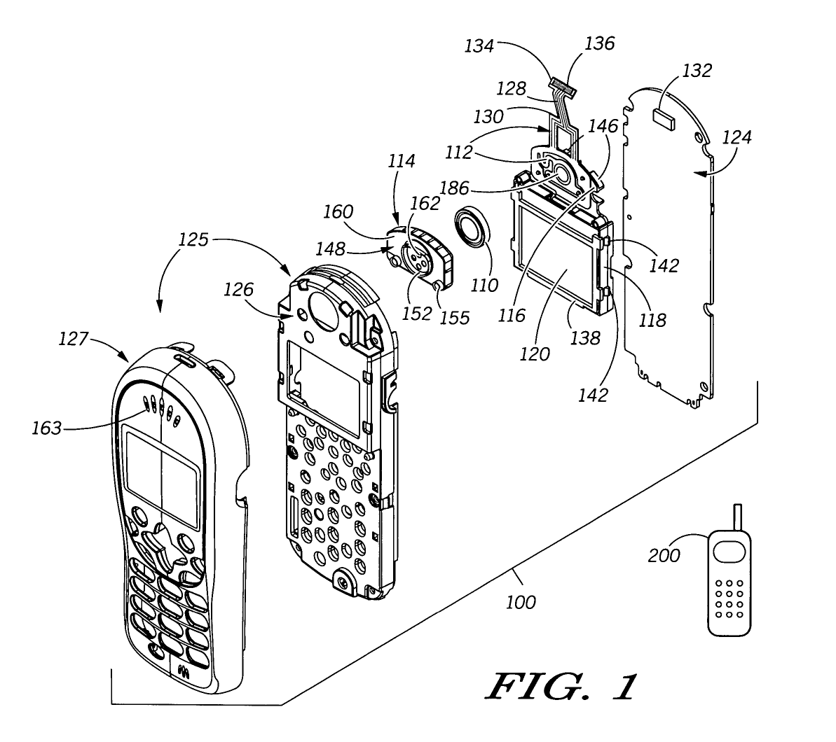

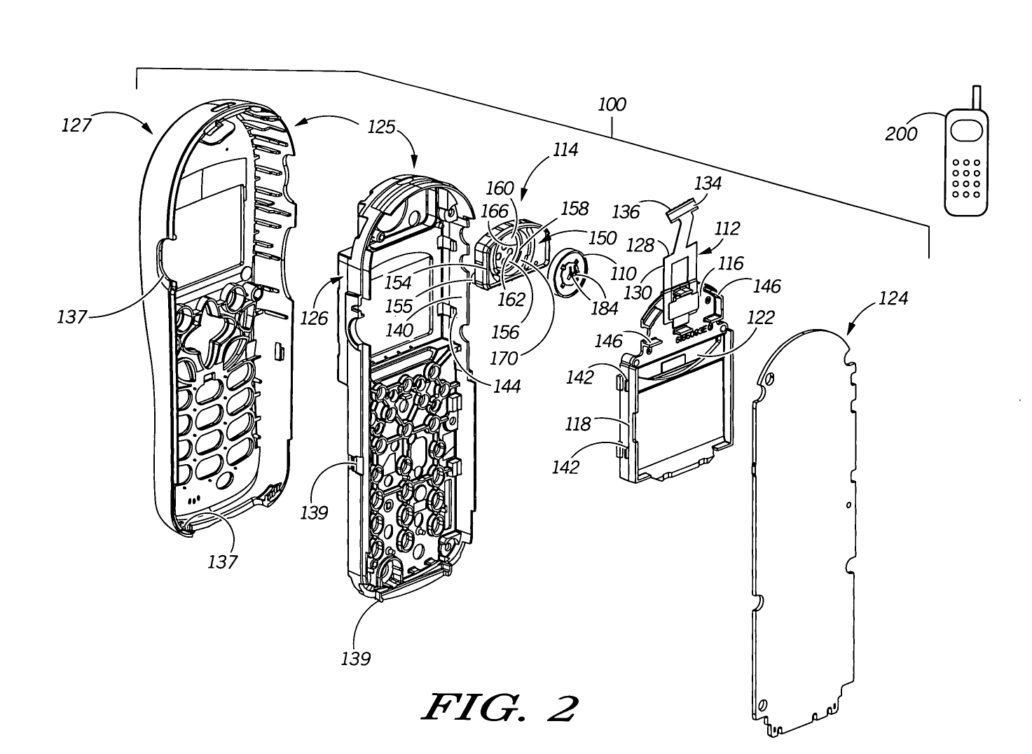

Referring now to FIGS. 1 and 2, exploded views of a transducer assembly 100 in accordance with the inventive arrangements are shown (FIG. 1 is a frontal view of the transducer assembly 100, while FIG. 2 is a rear view of the transducer assembly 100). The transducer assembly 100 can include a transducer 110, a flexible circuit element 112 and a transducer seal 114. In one arrangement, the transducer 110 can be an audio transducer (a speaker). It is understood, however, that the invention is not limited in this regard, as any other suitable transducer may be incorporated into the transducer assembly 100. As an example and without limitation, the transducer seal 114 can be generally constructed of a flexible material such as rubber or plastic.

The transducer assembly 100 may also include an extension 116 of a lightguide 118, a display 120 (see FIG. 1), a reflective backing 122 (see FIG. 2), a circuit board 124 and a cover 125. The cover 125 can include a housing 126 and a bezel 127. Each of the components discussed thus far can be housed within a telecommunications device 200, although one or more of them may be incorporated into any other suitable device. In one arrangement, the telecommunications device 200 can be a dual communication mode mobile unit that supports both cellular telephone service and dispatch service. As will be explained in detail below, the transducer seal 114 can seal the transducer 110 when the transducer seal 114 is positioned between the cover 125 and the flexible circuit element 112.

The flexible circuit element 112 can include runners or conductors 128 placed on a flexible substrate 130. In one arrangement, the flexible circuit element 112 can be coupled to the display 120 and the circuit board 124, which can permit the transfer of signals between the display 120 and the circuit board 124. As an example and without limitation, the display 120 can be a liquid crystal display, and the circuit board 124 can be a printed circuit board.

In another arrangement, the circuit board 124 may include a zero insertion force (ZIF) connector 132 (see FIG. 1) or any other suitable structure for receiving the flexible circuit element 112. For example, the flexible circuit element 112 can include a tab 134 having a plurality of termination pads 136, and the ZIF connector 132 can include suitable structure for receiving the terminations pads 136. The flexible circuit element 112 can be electrically coupled to the display 120 in a similar manner.

The lightguide 118 can secure the display 120. As an example, the display 120 can be engaged with the lightguide 118 by a snap fit, although other means of securing the display 120 to the lightguide 118 may be used. As is known to those of ordinary skill in the art, the lightguide 118 can direct light from a light source (not shown) such as a number of LEDs for backlighting, in a uniformly dispersed manner, the display 120. The reflective backing 122 (see FIG. 2) can be positioned below the display 120 for purposes of backlighting the display 120.

The lightguide 118 can include one or more angled tabs 142 that can engage one or more corresponding projections 144 (see FIG. 2), which can be mounted on an inner surface 140 of the housing 126. This engagement between the tabs 142 and the projections 144 can be a snap fit, which can permit the display 120 and the lightguide 118 to be secured to the housing 126 without the use of any fasteners, such as screws.

In one embodiment, a seal 138 (see FIG. 1) can be placed along the outer edges of the display 120. The seal 138 can provide a sealing interference fit between the display 120 and the inner surface 140 (see FIG. 2) of the housing 126 when the lightguide 118 is engaged with the housing 126. For purposes of the invention, a sealing interference fit can be any contact or mating between two or more elements in which there is deformation of at least one of the elements. This deformation can be temporary, a feature that can be provided by a flexible material, such as rubber.

As best shown In FIG. 2, the bezel 127 can include one or more tabs 137, and the housing 126 can include one or more corresponding tabs 139. The bezel 127 can receive the housing 126, and the tabs 137 can snap-engage the corresponding tabs 139 to secure the housing 126 to the bezel 127. Similar to the engagement of the lightguide 118 to the housing 126, the engagement of the housing 126 to the bezel 127 requires no fasteners. Of course, any other suitable structure can be used to engage the housing 126 with the bezel 127.

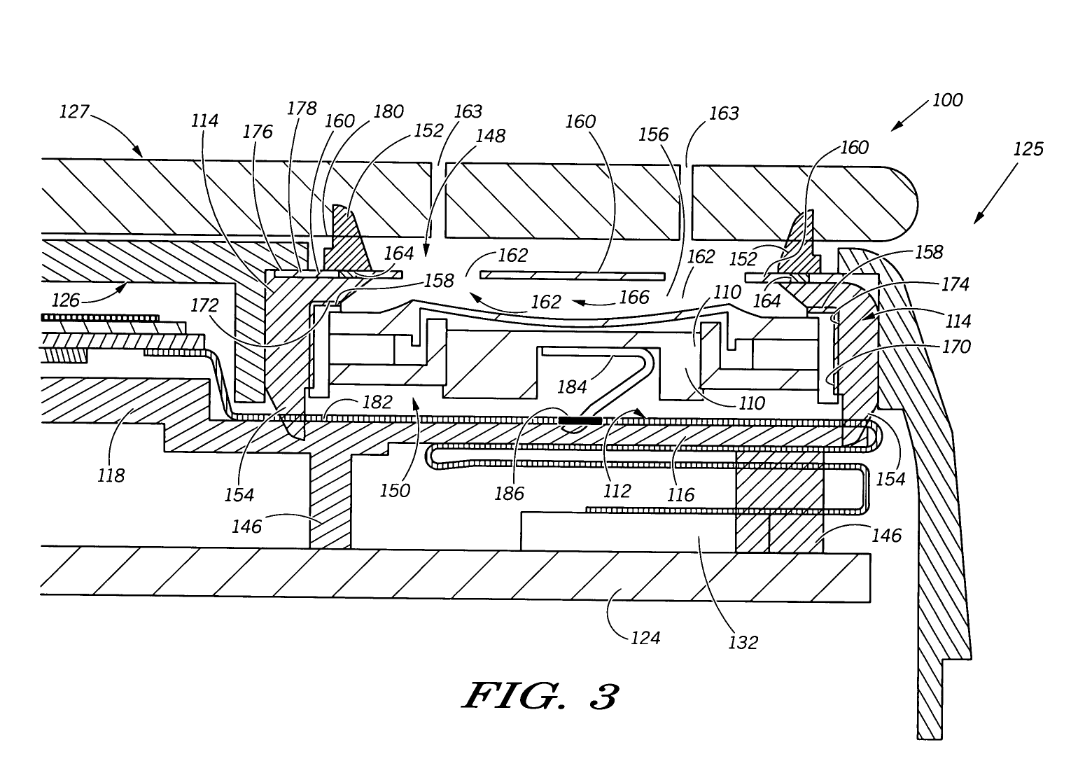

The extension 116 of the lightguide 118 can include one or more legs 146. Referring to FIG. 3, a cross-sectional view of the transducer assembly 100 is shown. When the lightguide 118 is engaged with the housing 126, one or more of the legs 146 can rest on the circuit board 124. The legs 146 can supplement the engagement of the lightguide 118 to the cover 125 because their contact with the circuit board 124 can help keep the lightguide 118 in place. Such a configuration can be particularly useful if the lightguide 118 were to be dislodged from its engagement with the housing 126.

As also shown in FIG. 3, the extension 116 of the lightguide 118 can be positioned above the circuit board 124. In view of this configuration, at least a portion of one or more circuit elements, such as resistors, capacitors, integrated circuits or any other suitable electronic or mechanical component, can be mounted on the circuit board 124 in an area below the extension 116. As an example, the ZIF connector 132, which can receive the flexible circuit element 112, is shown disposed on the circuit board 124 below the extension 116 of the lightguide 118. In addition, at least a portion of the flexible circuit element 112 can be positioned on and secured to the extension 116 of the lightguide 118. An adhesive can secure this portion of the flexible circuit element 112 to the extension 116, although other suitable techniques may be used to secure the flexible circuit element 112 to the extension 116.

Referring to FIGS. 1, 2 and 3, the transducer seal 114 can have a front portion 148 and a back portion 150. The front portion 148 can include a first rim 152 (best seen in FIGS. 1 and 3), and the back portion 150 can have a second rim 154 (best seen in FIGS. 2 and 3). The transducer seal 114 can also include an aperture 156, and as best seen in FIG. 3, the first rim 152 can include a bottom surface 158 at which the aperture 156 can terminate. As shown in FIGS. 1 and 2, the transducer seal 114 may include one or more back volume ports 155. Back volume ports are a well-known feature in the art and, accordingly, warrant no further discussion here.

Referring once again to FIGS. 1, 2 and 3, the front portion 148 of the transducer seal 114 can also include a plate 160. As shown in FIGS. 2 and 3, the plate 160 can cover a first end 166 of the aperture 156, and at least a portion of the first rim 152 can extend above the plate 160. In one arrangement, the plate 160 can be constructed of a rigid material such as steel, which can provide rigidity to at least a portion of the transducer seal 114. The plate 160 can include one or more apertures 162 for permitting the passage of audio from the transducer 114 to the outside environment. The bezel 127 can also include one or more apertures 163 for permitting the passage of such audio (see FIGS. 1 and 3).

As shown in FIG. 3, the plate 160 can also include one or more channels 164. In one embodiment, during assembly of the transducer seal 114, the material that comprises the transducer seal 114 (other than the plate 160) can be permitted to flow through the channels 164. This material, when cured, can form the portion of the first rim 152 that extends above the plate 160. It is understood, however, that the invention is in no way limited to this particular example, as any other suitable method can be used to create the portion of the first rim 152 that extends above the plate 160.

Referring to FIGS. 2 and 3, the transducer 110 can be inserted in the aperture 156, and the transducer 110 can engage the bottom surface 158 of the first rim 152. In addition, the transducer 110 can engage an inner surface 170 of the aperture 156 of the transducer seal 114. Specifically, referring to FIG. 3, a frontal surface 172 of the transducer 110 can engage the bottom surface 158 of the first rim 152, and an outer surface 174 of the transducer 110 can engage the inner surface 170 of the aperture 156. As noted earlier, the transducer seal 114 can generally be constructed of a flexible material (other than the plate 160). Thus, the bottom surface 158 of the first rim 152 of the transducer seal 114 can engage the frontal surface 172 of the transducer 110 with a sealing interference fit (the overlapping surfaces represent a sealing interference fit). Similarly, the inner surface 170 of the aperture 156 of the transducer seal 114 can engage the outer surface 174 of the transducer 110 with a sealing interference fit.

As also shown in FIG. 3, the transducer seal 114 can be positioned against the housing 126. Namely, a frontal surface 176 of the transducer seal 114, which can include portions of the first rim 152 and the plate 160, can be positioned against an inner surface 178 of the housing 126. Moreover, when the housing 126 is engaged with the bezel 127, the first rim 152 can engage the bezel 127. In particular, a portion of the first rim 152 can engage an inner surface 180 of the bezel 127 with a sealing interference fit.

When the transducer seal 114 is positioned against the housing 126 and the lightguide 118 is engaged with the housing 126, the second rim 154 of the back portion 150 of the transducer seal 114 can engage the flexible circuit element 112. Specifically, the second rim 154 can engage a top surface 182 of the flexible circuit element 112 with a sealing interference fit. As a result of the engagements presented above, the transducer seal 114 can seal the transducer 110. The seal that is formed can prevent high audio from leaking through the transducer 114, a condition that may injure a user, or at least present an annoying condition.

Referring to FIGS. 2 and 3, the transducer 110 can include one or more spring contacts 184, which can couple the transducer 110 to the flexible circuit element 112. This coupling between the spring contacts 184 and the flexible circuit element 112 can allow the transfer of electrical signals between the flexible circuit element 112 (from the circuit board 124) and the transducer 110. In one arrangement, the flexible circuit element 112 can include a conducting surface 186. As an example, the spring contacts 184 can be flexible, which can provide for some tolerance in the connection between the spring contacts 184 and the conducting surface 186. As best shown in FIG. 3, when the transducer 110 is positioned within the transducer seal 114, the spring contacts 184 can contact the conducting surface 186, thereby providing a signal path between the transducer 110 and the flexible circuit element 112.

While the preferred embodiments of the invention have been illustrated and described, it will be clear that the invention is not so limited. Numerous modifications, changes, variations, substitutions and equivalents will occur to those skilled in the art without departing from the spirit and scope of the present invention as defined by the appended claims.

What is claimed is:

1. A transducer assembly, comprising:
a transducer;
a flexible circuit element, wherein said transducer is coupled to said flexible circuit element; and
a transducer seal, wherein said transducer seal seals said transducer when said transducer seal is positioned between a cover and said flexible circuit element.

2. The transducer assembly according to claim 1, wherein said flexible circuit element is coupled to a display and a circuit board, said display, said circuit board, said transducer, said flexible circuit element and said transducer seal being housed within a telecommunications device.

3. The transducer assembly according to claim 2, wherein said circuit board includes a zero insertion force connector for receiving said flexible circuit element.

4. The transducer assembly according to claim 1, further comprising an extension of a lightguide, at least a portion of said flexible circuit element being positioned on and secured to said extension of said lightguide.

5. The transducer assembly according to claim 4, wherein said extension of said lightguide is positioned above a circuit board housed in a telecommunications device and wherein at least a portion of at least one circuit element is mountable on said circuit board in an area that is below said extension of said lightguide.

6. The transducer assembly according to claim 4, wherein said cover comprises a housing and a bezel, said housing engages said bezel and said lightguide engages said housing, wherein when said lightguide engages said housing and said housing engages said bezel, said transducer seal is positioned against said housing and said bezel.

7. The transducer assembly according to claim 6, wherein said transducer seal comprises a front portion having a first rim and a back portion having a second rim.

8. The transducer assembly according to claim 7, wherein when said transducer seal is positioned against said housing and said bezel, said first rim of said front portion of said transducer seal engages said bezel with a sealing interference fit.

9. The transducer assembly according to claim 7, wherein when said transducer seal is positioned against said housing and said lightguide engages said housing, said second rim of said back portion of said transducer seal engages said flexible circuit element with a sealing interference fit.

10. The transducer assembly according to claim 1, wherein said transducer includes at least one spring contact for coupling said transducer to said flexible circuit element.

11. The transducer assembly according to claim 1, wherein said transducer seal comprises an aperture for receiving said transducer, a plate that covers a first end of said aperture and a first rim.

12. The transducer assembly according to claim 11, wherein at least a portion of said first rim extends above said plate.

13. The transducer assembly according to claim 11, wherein when said transducer is inserted into said aperture, a bottom surface of said first rim of said transducer seal engages said transducer with a sealing interference fit and an inner surface of said aperture of said transducer seal engages said transducer with a sealing interference fit.

14. The assembly according to claim 1, wherein said transducer seal is constructed of at least one of rubber and plastic.

15. The transducer assembly according to claim 1, wherein said seal that is formed prevents high audio leakage through said transducer assembly.

16. The transducer assembly according to claim 5, wherein said extension of said lightguide includes at least one leg, said leg being positioned against a surface of said circuit board for supplementally supporting said lightguide.

17. A transducer assembly, comprising:
a transducer;
a flexible circuit element, wherein said transducer is coupled to said flexible circuit element;
an extension of a lightguide, wherein at least a portion of said flexible circuit element is positioned on and secured to said extension of said lightguide; and
a transducer seal, wherein said transducer seal seals said transducer when said transducer seal is positioned between a cover and said flexible circuit element.

18. A method for producing a transducer assembly, comprising the steps of:
providing a transducer and a flexible circuit element;
coupling the transducer to the flexible circuit element; and
positioning a transducer seal between a cover and the flexible circuit element to seal the transducer.

19. The method according to claim 18, further comprising the steps of:
providing an extension of a lightguide; and
securing the flexible circuit element to the extension of the lightgiuide.

20. The method according to claim 19, further comprising the step of positioning the lightguide above a circuit board housed in a telecommunications device, wherein at least a portion of at least one circuit element is mountable on the circuit board in an area that is below the extension of the lightguide.
